(19) United States
(12) Patent Application Publication
(10) Pub. No.: US 2022/0163888 A1
(43) Pub. Date: May 26, 2022

(54) POSITIVE TYPE RESIST COMPOSITION AND METHOD FOR MANUFACTURING RESIST PATTERN USING THE SAME

(71) Applicant: Merck Patent GmbH, Darmstadt (DE)

(72) Inventors: Kazumichi AKASHI, Kakegawa-shi (JP); Yoshiko URABE, Kakegawa-shi (JP); Rui ZHANG, Kakegawa-shi (JP); Tomohide KATAYAMA, Kakegawa-shi (JP)

(21) Appl. No.: 17/599,093

(22) PCT Filed: Mar. 26, 2020
(86) PCT No.: PCT/EP2020/058495

§ 371 Date: Sep. 28, 2021

(30) Foreign Application Priority Data
Mar. 28, 2019 (JP) 2019-063192

(51) Int. Cl. G03F 7/039; G03F 7/32; G03F 7/004; G03F 7/38; G03F 7/40; G03F 7/20

(52) U.S. Cl. CPC G03F 7/0392; G03F 7/322; G03F 7/2006; G03F 7/38; G03F 7/40; G03F 7/0045

(57) ABSTRACT

A positive type resist composition capable of forming a pattern shape suitable for lift-off is provided. A positive type resist composition comprising (A) a certain polymer, (B) an acid generator having an imide group, (C) a dissolution rate modifier and (D) a solvent.

### BACKGROUND OF THE INVENTION

### Technical Field

The present invention relates to a positive type resist composition to be used in manufacturing a semiconductor device, a semiconductor integrated circuit, and the like, and a method for manufacturing a resist pattern using the same.

### Background Art

In a process of manufacturing a device such as a semiconductor, fine processing by lithographic technique using a photoresist has generally been employed. The fine processing process comprises forming a thin photoresist layer on a semiconductor substrate such as a silicon wafer, covering the layer with a mask pattern corresponding to a desired device pattern, exposing the layer with actinic ray such as ultraviolet ray through the mask, developing the exposed layer to obtain a photoresist pattern, and processing the substrate using the resulting photoresist pattern as a protective film, thereby forming fine unevenness corresponding to the above-described pattern.

In the case of using a positive type resist composition, the exposed area of the resist film formed by coating the composition is increased in alkali solubility by the acid generated by the exposure, and is dissolved in the developer to form a pattern. In general, exposure light does not sufficiently reach the lower part of the resist film, generation of acid is suppressed in the lower part of the resist film, and acid generated in the lower part of the resist film is deactivated due to the influence of the substrate. Therefore, a resist pattern formed using a positive type resist composition tends to become a tapered shape (a footing shape) (Patent Document 1).

A lift-off method is known, which comprises forming a film of a material such as metal on the formed resist pattern by vapor deposition or the like, removing the resist by a solvent, thereby removing the material on the resist pattern and remaining the material such as metal only in an area where the resist pattern is not formed.

In order to perform the lift-off method, a negative type resist composition is often used since a resist pattern having a reverse tapered shape is preferable. In Patent Document 2, although it is to create a partition for not a semiconductor but an EL display device and processes are different and required accuracy and sensitivity are also different, an attempt was made to form a reverse tapered shape. However, the resist compositions used were all negative type, and in addition, the reverse taper was realized with a part of them.

On the other hand, it has been studied to generate an undercut at the bottom of a resist pattern obtained from a positive type resist composition to form a T-type (for example, Patent Documents 3 to 5). These compositions require a certain polymer or contain a novolak resin and a naphthoquinone diazide-based photosensitizer as essential components.

### PRIOR ART DOCUMENTS

### Patent Documents

[Patent document 1] WO2011/102064
[Patent document 2] JP-A 2005-148391
[Patent document 3] JP-A 2012-108415
[Patent document 4] JP-A 2001-235872
[Patent document 5] JP-A H8-69111

### SUMMARY OF THE INVENTION

### Problems to be Solved by the Invention

The present inventors considered that there are one or more problems still need improvements in resist compositions and use thereof. These include, for example, the followings: resist pattern shapes suitable for lift-off cannot be formed; sensitivity of the resist composition is insufficient; sufficient resolution cannot be obtained; environmental affect is received in the resist pattern manufacturing process; any resist pattern of thick film cannot be manufactured; solubility of solid component in solvent is poor; in the case of T-type resist pattern, when the deposited metal is thick, the remover cannot invade the resist sidewall; solubility in the remover is low; any resist pattern with a high aspect ratio cannot be formed; there are many cracks in the resist film; the number of defects is large; and storage stability is poor.

The present invention has been made to solve the above-described problems, and provides a positive type resist composition and a method for manufacturing a resist pattern using the same.

### Means for Solving the Problems

The positive type thick film resist composition comprises:

(A) at least one polymer selected from the group consisting of:

polymer P comprising a repeating unit selected from the group consisting of the formulae (P-1) to (P-4):

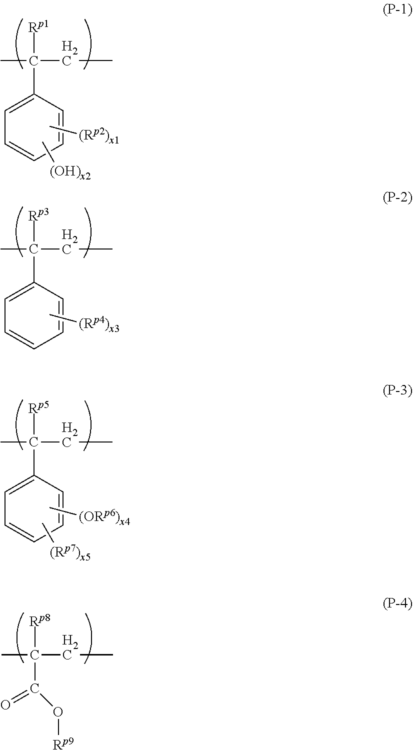

(wherein,

R^{p1}, R^{p3}, R^{p5} and R^{p8} are each independently C₁₋₅ alkyl, C₁₋₅ alkoxy or —COOH,

R^{p2}, R^{p4} and R^{p7} are each independently C₁₋₅ alkyl (where —CH₂— in alkyl can be replaced with —O—),

R^{p6} and R^{p9} are each independently C₁₋₅ alkyl (where —CH₂— in alkyl can be replaced with —O—),

x1 is 0 to 4,

x2 is 1 to 2, provided that x1+x2≤5,

x3 is 0 to 5,

x4 is 1 to 2,

x5 is 0 to 4, provided that x4+x5≤5), and

polymer Q comprising a repeating unit represented by the formula (Q-1):

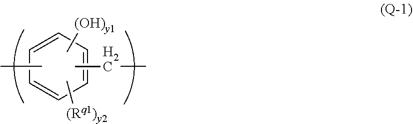

(wherein,

R^{q1} is independently C₁₋₅ alkyl,

y1 is 1 to 2, and

y2 is 0 to 3, provided that y1+y2≤4),

provided that the total mass of the polymer P (Mₚ) and the total mass of the polymer Q (M_{q}) in the composition satisfy the formulae: 0<Mₚ/(Mₚ+M_{q})≤100% and 0≤M_{q}/(Mₚ+M_{q})<70%;

(B) an acid generator having an imide group;

(C) a dissolution rate modifier, which is a compound in which two or more of phenol structures are bonded by a hydrocarbon group optionally substituted by oxy; and

(D) a solvent.

Further, the method for manufacturing a resist pattern according to the present invention comprises the following processes:

(1) applying the above-described composition above a substrate;

(2) heating said composition to form a resist layer;

(3) exposing said resist layer;

(4) subjecting said resist layer to post exposure bake; and

(5) developing said resist layer.

### Effects of the Invention

Using the positive type resist composition of the present invention, one or more of the following effects can be desired.

Resist pattern shapes suitable for lift-off can be formed. Sufficient sensitivity of the resist composition can be obtained. Sufficient resolution can be obtained. Environmental affect can be reduced in manufacturing the resist pattern. Resist pattern of thick film can be manufactured. Solubility of solid component in solvent is good. Even if the deposited metal is thick, it is possible to obtain a resist pattern shape that allows the remover to invade the resist sidewall. Solubility in the remover is high. Resist pattern with a high aspect ratio can be formed. Cracks in the resist film can be suppressed. The number of defects can be reduced. Storage stability is good.

It is an advantage of the present invention that solubility in the remover is high and the shape of the resist pattern is suitable.

### BRIEF DESCRIPTION OF THE DRAWINGS

FIG. 1: Schematic sectional views for explaining a resist pattern of reverse tapered shape, a resist pattern of overhanging shape, and a modified example of the resist pattern of overhanging shape.

FIG. 2: A photomicrograph of a resist pattern of reverse tapered shape, and a schematic sectional view thereof.

### DETAILED DESCRIPTION OF THE INVENTION

### Mode for Carrying Out the Invention

### Definitions

Unless otherwise specified in the present specification, the definitions and examples described in this “Definitions” paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When polymer has a plural types of repeating units, these repeating units copolymerize. These copolymerization may be any of alternating copolymerization, random copolymerization, block copolymerization, graft copolymerization, or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

Embodiments of the present invention are described below in detail.

<Positive Type Resist Composition>

The positive type resist composition according to the present invention (hereinafter sometimes referred to as the composition) comprises (A) a certain polymer, (B) an acid generator having an imide group, (C) a dissolution rate modifier, and (D) a solvent.

The viscosity of the composition according to the present invention is preferably 50 to 2,000 cP, and more preferably 200 to 1,500 cP. Here, the viscosity is measured at 25° C. with a capillary viscometer.

The composition according to the present invention is preferably a composition forming thick film resist. Here, in the present invention, the thick film means a film thickness of 1 to 50 μm, preferably 5 to 15 μm, and the thin film means a film thickness of less than 1 μm.

With respect to the composition according to the present invention, light having a wavelength of 190 to 440 nm, preferably 240 to 440 nm, more preferably 360 to 440 nm, and still more preferably 365 nm is preferably used for the exposure to be carried out later.

The composition according to the present invention is preferably a positive type resist composition forming reverse tapered shape. In the present invention, the “reverse tapered shape” is described later.

The composition according to the present invention is preferably a positive type lift-off resist composition.

(A) Polymer

The polymer (A) comprises the polymer P or a combination of the polymer P and the polymer Q. Needless to describe, when the polymer P and the polymer Q are jointly contained, they are not copolymerized.

[Polymer P]

The polymer P used in the present invention reacts with an acid to increase the solubility in an alkaline aqueous solution. This kind of polymer has, for example, an acid group protected by a protecting group, and when an acid is added from the outside, the protecting group is eliminated and the solubility in an alkaline aqueous solution increases.

The polymer P comprises a repeating unit selected from the group consisting of the formulae (P-1) to (P-4):

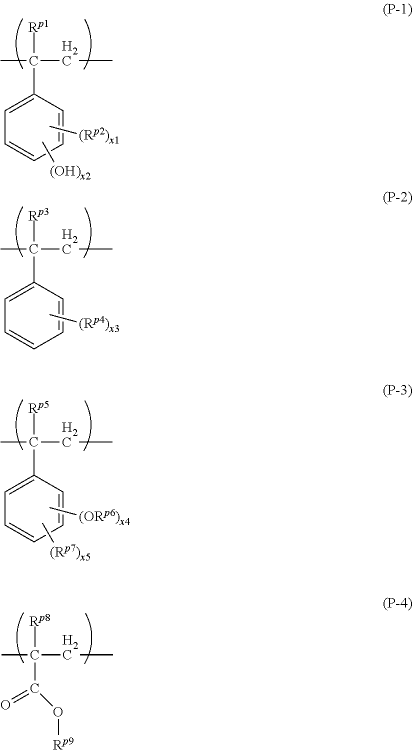

(wherein,

R^{p1}, R^{p3}, R^{p5} and R^{p8} are each independently C₁₋₅ alkyl, C₁₋₅ alkoxy or —COOH,

R^{p2}, R^{p4} and R^{p7} are each independently C₁₋₅ alkyl (where —CH₂— in alkyl can be replaced with —O—),

R^{p6} and R^{p9} are each independently C₁₋₅ alkyl (where —CH₂— in alkyl can be replaced with —O—),

x1 is 0 to 4,

x2 is 1 to 2, provided that x1+x2≤5,

x3 is 0 to 5,

x4 is 1 to 2, and

x5 is 0 to 4, provided that x4+x5≤5).

In one embodiment of the polymer P of the present invention, it is possible that the polymer P has only (P-1) as a structural unit and that the ratio of (P-1) wherein x2=1 and (P-1) wherein x2=2 is 1:1. In this case, it becomes that x2=1.5. Hereinafter, the same applies to any polymer unless otherwise specified.

In the formula (P-1),

R^{p1} is preferably hydrogen or methyl, and more preferably hydrogen. R^{p2} is preferably methyl, ethyl, t-butyl or methoxy, and more preferably methyl or t-butyl.

x2 is preferably 1 or 2, and more preferably 1.

x1 is preferably 0, 1, 2, or 3, and more preferably 0.

An exemplified embodiment of the formula (P-1) is as shown below:

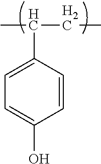

In the formula (P-2),

R^{p3} is preferably hydrogen or methyl, and more preferably hydrogen. R^{p4} is preferably methyl, ethyl, t-butyl or methoxy, and more preferably methyl or t-butyl.

x3 is preferably 0, 1, 2, or 3, and more preferably 0.

An exemplified embodiment of the formula (P-2) is as shown below:

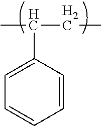

In the formula (P-3),

R^{p5} is preferably hydrogen or methyl, and more preferably hydrogen. R^{p6} is preferably methyl, ethyl, propyl, t-butyl, —CH(CH₃)—O—C₂H₅ or —CH(CH₃)—O—CH₃, more preferably methyl, butyl, —CH(CH₃)—O—C₂H₅ or —CH(CH₃)—O—CH₃, and further preferably t-butyl or —CH(CH₃)—O—C₂H₅. R^{p7} is preferably methyl, ethyl, t-butyl or methoxy, and more preferably methyl or t-butyl.

x4 is preferably 1 or 2, and more preferably 1.

x5 is preferably 0, 1, 2, or 3, and more preferably 0.

An exemplified embodiment of the formula (P-3) is as shown below:

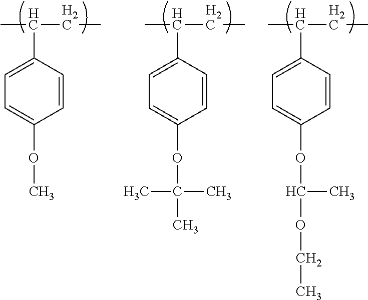

In the formula (P-4),

R^{p8} is preferably hydrogen or methyl, and more preferably hydrogen. R^{p9} is preferably methyl, ethyl, propyl or t-butyl, and more preferably t-butyl.

An exemplified embodiment of the formula (P-4) is as shown below:

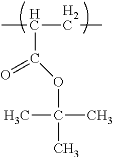

Since these structural units are appropriately blended depending on the purpose, the blending ratio thereof is not particularly limited, but it is preferably blended so that the increasing ratio of the solubility in an alkaline aqueous solution is made appropriate by an acid.

Preferably, in the polymer (A), nₚ₁, nₚ₂, nₚ₃ and nₚ₄, which are the numbers of repeating units respectively of the formulae (P-1), (P-2), (P-3) and (P-4), satisfy the following formulae:

30%≤nₚ₁/(nₚ₁+nₚ₂+nₚ₃+nₚ₄)≤90%,

0%≤nₚ₂/(nₚ₁+nₚ₂+nₚ₃+nₚ₄)≤40%,

0%≤nₚ₃/(nₚ₁+nₚ₂+nₚ₃+nₚ₄)≤40%, and

0%≤nₚ₁/(nₚ₁+nₚ₂+nₚ₃+nₚ₄)≤40%.

Nₚ₁/(nₚ₁+nₚ₂+nₚ₃+nₚ₄) is more preferably 40 to 80%, and further preferably 40 to 70%.

nₚ₂/(nₚ₁+nₚ₂+nₚ₃+nₚ₄) is more preferably 0 to 30%, and further preferably 10 to 30%.

Nₚ₃/(nₚ₁+nₚ₂+nₚ₃+nₚ₄) is more preferably 0 to 30%, and further preferably 10 to 30%. It is a preferable aspect in which nₚ₃/(nₚ₁+nₚ₂+nₚ₃+nₚ₄) is 0%.

Nₚ₄/(nₚ₁+nₚ₂+nₚ₃+nₚ₄) is more preferably 10 to 40%, and further preferably 10 to 30%.

Further, (nₚ₃+nₚ₄)/(nₚ₁+nₚ₂+nₚ₃+nₚ₄) is preferably 0 to 40%, more preferably 0 to 30%, and further preferably 10 to 30%. In the polymer P, it is also a preferable aspect that any one of the repeating units of the formulae (P-3) and (P-4) is present and the other is not present.

The polymer P can also comprise structural units other than (P-1) to (P-4). Here, it is preferable that the total number of all repeating units contained in the polymer P (nₜₒₜₐₗ) satisfies the following formula:

80%≤(nₚ₁+nₚ₂+nₚ₃+nₚ₄)/nₜₒₜₐₗ≤100%.

(nₚ₁+nₚ₂+nₚ₃+nₚ₄)/nₜₒₜₐₗ is more preferably 90 to 100%, and further preferably 95 to 100%. It is also a preferred aspect of the present invention that (nₚ₁+nₚ₂+nₚ₃+nₚ₄)/nₜₒₜₐₗ=100%, that is, any structural unit other than (P-1) to (P-4) is not contained.

Exemplified embodiments of the polymer P are as shown below:

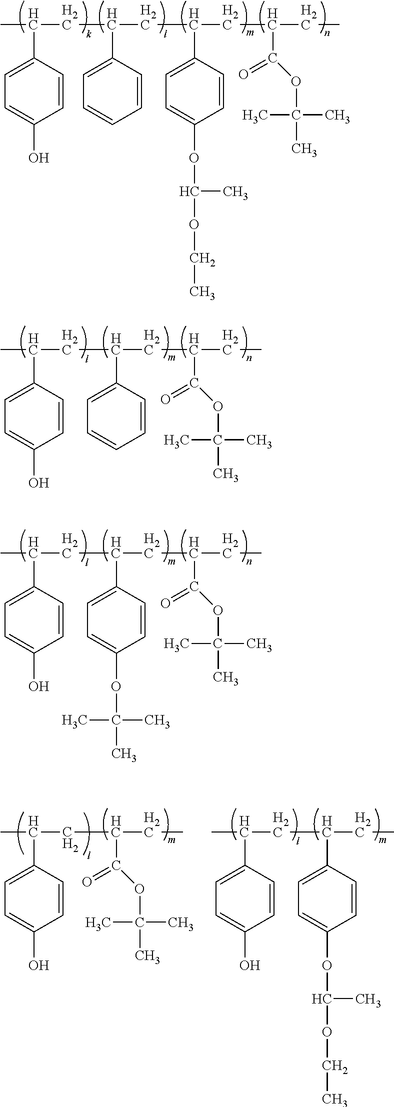

The mass average molecular weight (hereinafter sometimes referred to as Mw) of the polymer P is preferably 5,000 to 50,000, more preferably 7,000 to 30,000, and further preferably 10,000 to 15,000.

In the present invention, Mw can be measured by gel permeation chromatography (GPC). In this measurement, it is a preferable example to use a GPC column at 40 degrees Celsius, an elution solvent tetrahydrofuran at 0.6 mL/min, and monodisperse polystyrene as a standard. This is the same hereinafter as well.

[Polymer Q]

The polymer Q used in the present invention is a novolak polymer that is generally used in lithography, and is obtained, for example, by a condensation reaction of phenols and formaldehyde.

The polymer Q comprises a repeating unit represented by the formula (Q-1):

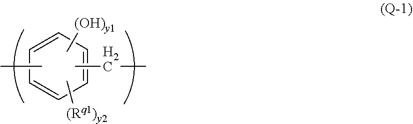

wherein,

R^{q1} is independently C₁₋₅ alkyl,

y1 is 1 to 2 and y2 is 0 to 3, provided that y1+y2≤4.

y1 is preferably 1 or 2, and more preferably 1.

y2 is preferably 0 to 2, and more preferably 0.5 to 1.5.

The polymer Q preferably comprises a repeating unit selected from the group consisting of the formulae (Q-1a) to (Q-1d):

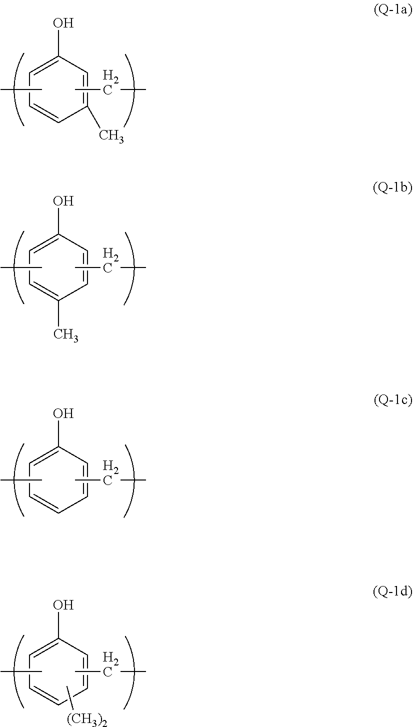

N_{qa} that is the number of the repeating unit of (Q-1a), N_{qb} that is the number of the repeating unit of (Q-1b), N_{qc} that is the number of the repeating unit of (Q-1c), and N_{qd} that is the number of the repeating unit of (Q-1d) preferably satisfy the following formulae:

30%≤N_{qa}/(N_{qa}+N_{qb}+N_{qc}+N_{qd})≤100%;

0%≤N_{qb}/(N_{qa}+N_{qb}+N_{qc}+N_{qd})≤70%;

0%≤N_{qc}/(N_{qa}+N_{qb}+N_{qc}+N_{qd})≤50%; and

0%≤N_{qd}/(N_{qa}+N_{qb}+N_{qc}+N_{qd})≤70%.

N_{qa}/(N_{qa}+N_{qb}+N_{qc}+N_{qd}) is more preferably 30 to 80%, further preferably 30 to 70%, and still more preferably 40 to 60%.

N_{qb}/(N_{qa}+N_{qb}+N_{qc}+N_{qd}) is more preferably 10 to 60%, further preferably 20 to 50%, and still more preferably 30 to 50%.

N_{qc}/(N_{qa}+N_{qb}+N_{qc}+N_{qd}) is more preferably 0 to 40%, and further preferably 10 to 30%. It is also a preferred embodiment that N_{qc}/(N_{qa}+N_{qb}+N_{qc}+N_{qd}) is 0%.

N_{qd}/(N_{qa}+N_{qb}+N_{qc}+N_{qd}) is more preferably 0 to 40%, and further preferably 10 to 30%. It is also a preferred embodiment that N_{qd}/(N_{qa}+N_{qb}+N_{qc}+N_{qd}) is 0%. In the polymer Q, it is also a preferable aspect that any one of the repeating units of the formulae (Q-1c) and (Q-1d) is present and the other is not present.

The polymer Q can also comprise structural units other than (Q-1a) to (Q-1d). Here, the total number of all repeating units contained in the polymer Q (Nₜₒₜₐₗ), preferably satisfies the following formula:

80%≤(N_{qa}+N_{qb}+N_{qc}+N_{qd})/Nₜₒₜₐₗ≤100%

(N_{qa}+N_{qb}+N_{qc}+N_{qd})/Nₜₒₜₐₗ is more preferably 90 to 100%, and further preferably 95 to 100%. It is also a preferred aspect of the present invention that (N_{qa}+N_{qb}+N_{qc}+N_{qd})/Nₜₒₜₐₗ=100%, that is, any structural unit other than (Q-1a) to (Q-1d) is not contained.

The mass average molecular weight (hereinafter sometimes referred to as Mw) of the polymer Q is preferably 1,000 to 50,000, more preferably 2,000 to 30,000, and further preferably 3,000 to 10,000.

The total mass of the polymer P (Mₚ) and the total mass of the polymer Q (M_{q}) in the composition preferably satisfy the formula: 0<Mₚ/(Mₚ+M_{q})≤100%, and it is more preferably to satisfy the formula: 40<Mₚ/(Mₚ+M_{q})≤90%.

Further, it is preferable to satisfy the formula: 0≤M_{q}/(Mₚ+M_{q})<70%, and it is more preferable to satisfy the formula: 10≤M_{q}/(Mₚ+M_{q})≤60%.

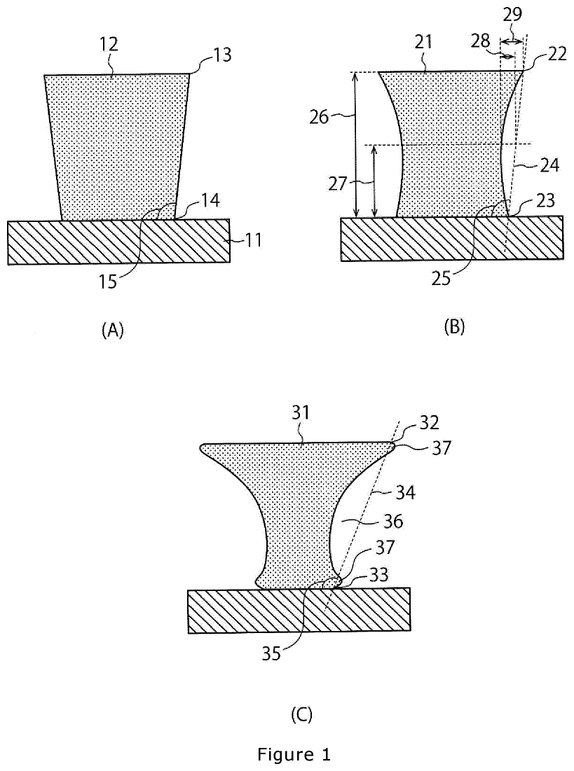

The polymer Q is a polymer having higher alkali solubility compared with the polymer P. In the polymer (A), the polymer Q may not be contained, but by including it, the resist pattern tends to be formed in an overhanging shape as shown in FIG. 1(B) described later. However, since the polymer Q has high alkali solubility, if the content of the polymer Q is 70% or more based on the total mass of the polymer P and Q, the sectional shape of the resist pattern tends to approach a tapered shape, to which attention should be paid.

The polymer (A) can contain other polymer than the polymer P and the polymer Q. The content of the other polymer than the polymer P and the polymer Q is preferably 60% or less, and more preferably 30% or less, based on the total mass of the polymer (A). The other polymer than the polymer P and the polymer Q copolymerizes with neither the polymer P nor the polymer Q.

The other polymer than the polymer P and the polymer Q does not satisfy the conditions of the polymer comprising the repeating unit selected from the group consisting of the above-described formulae (P-1) to (P-4), and in addition, it does not satisfy the conditions of the polymer comprising the repeating unit represented by the formula (Q-1).

It is also a preferred aspect of the present invention that no other polymer than the polymer P and the polymer Q is contained.

The content of the polymer (A) is preferably 10 to 50 mass %, and more preferably 30 to 40 mass %, based on the total mass of the composition.

(B) Acid Generator Having Imide Group

The composition according to the present invention comprises an acid generator having an imide group (B) (hereinafter sometimes referred to as the acid generator (B)). The acid generator (B) releases an acid upon irradiation with light, and the acid acts on the polymer P to play a role of increasing the solubility of the polymer in an alkaline aqueous solution. For example, when the polymer has an acid group protected by a protecting group, the protecting group is eliminated with an acid.

In the present invention, the acid generator (B) means a compound itself having the above-described function. Although the compound is sometimes dissolved or dispersed in a solvent and contained in the composition, such a solvent is preferably contained in the composition as the solvent (D) or other component. Hereinafter, the same applies to various additives that may be contained in the composition.

In addition, the imide group in the present invention means a group having a structure of —N<, and a structure in which a nitrogen atom is present between two carbonyls, such as —C(═O)—N(—Z)—C(═O)— (where Z is an organic group), is preferable.

In addition, it is preferred that the composition according to the present invention does not substantially contain a diazonaphthoquinone derivative and a quinonediazide sulfonic acid ester-based photosensitizer (hereinafter referred to as the diazonaphthoquinone derivative and the like in this paragraph) that are usually used as a photosensitizer for novolak polymer. In prior art documents such as Patent Documents 1 to 3, the diazonaphthoquinone derivative and the like are converted to carboxylic acids upon exposure and are used to increase the alkali solubility in the exposed part. On the other hand, the diazonaphthoquinone derivatives and the like are considered to contribute to dissolution inhibition by making the novolak polymer in the unexposed part (the part that is not exposed) have a high molecular weight.

When the composition according to the present invention contains the diazonaphthoquinone derivative and the like, the sectional shape of the resist pattern tends to come closer to a tapered shape. For this reason, it is a preferred embodiment that the composition according to the present invention contains no diazonaphthoquinone derivative and the like.

The acid generator (B) is preferably represented by the formula (b):

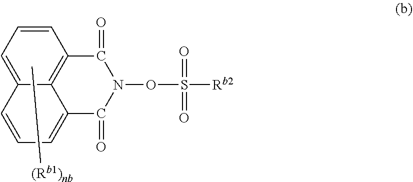

wherein,

R^{b1} is each independently C₃₋₁₀ alkenyl or alkynyl (where CH₃— in alkenyl and alkynyl can be substituted by phenyl, and —CH₂— in alkenyl and alkynyl can be replaced with at least any one of —C(═O)—, —O— or phenylene), C₂₋₁₀ thioalkyl or C₅₋₁₀ saturated heterocyclic ring,

nb is 0, 1 or 2, and

R^{b2} is C₁₋₅ fluorine-substituted alkyl. Here, as to the fluorine substitution, it is sufficient that at least one hydrogen atom is replaced with fluorine, but preferably all of hydrogen are substituted by fluorine.

Here, in the present invention, alkenyl means a monovalent group having one or more of double bonds (preferably one). Similarly, alkynyl means a monovalent group having one or more of triple bonds (preferably one).

R^{b1} is preferably C₃₋₁₂ alkenyl or alkynyl (where CH₃ in alkenyl and alkynyl can be substituted by phenyl, and —CH₂— in alkenyl and alkynyl can be replaced with at least any one of —C(═O)—, —O— or phenylene), C₃₋₅ thioalkyl or C₅₋₆ saturated heterocyclic ring.

Exemplified embodiments of R^{b1} include —C≡C—CH₂—CH₂—CH₂—CH₃, —CH═CH—C(═O)—O-tBu, —CH═CH-Ph, —S—CH(CH₃)₂, —CH═CH-Ph-O—CH(CH₃)—(CH₂CH₃) and piperidine. Here, tBu means t-butyl, and Ph means phenylene or phenyl. The same applies hereinafter unless otherwise specified.

nb is preferably 0 or 1, and more preferably nb=0. It is also a preferable aspect that nb=1.

R^{b2} is preferably C₁₋₄ alkyl in which all of hydrogen are fluorine-substituted, and more preferably C₁ or C₄ alkyl in which all of hydrogen are fluorine-substituted. The alkyl of R^{b2} is preferably linear.

Exemplified embodiments of the acid generator (B) are as shown below:

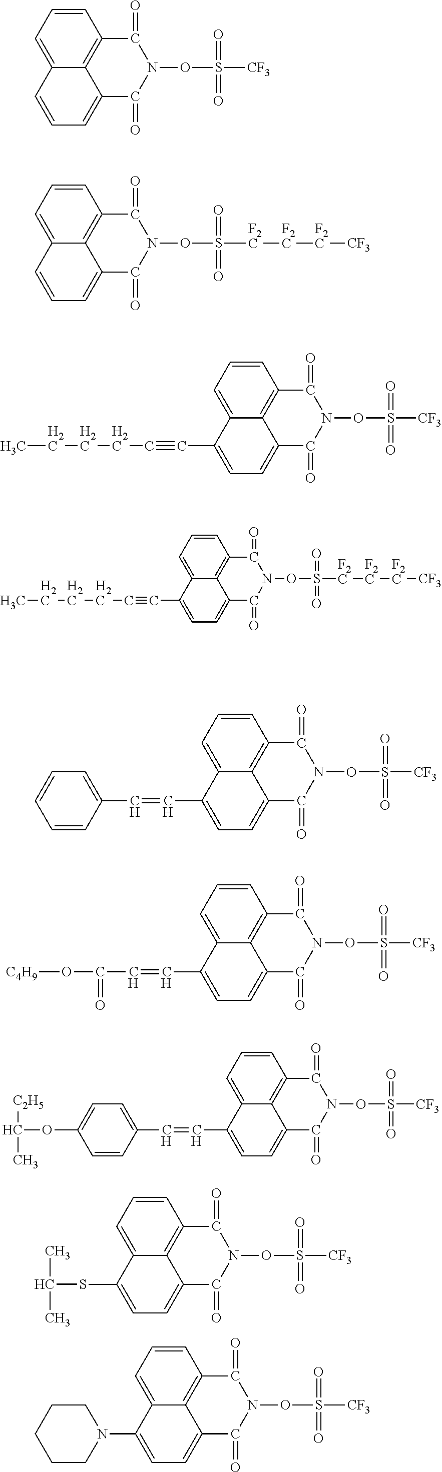

For example, the following exemplified embodiment can be represented by the formula (b). R^{b1} is originally C₈ alkenyl, which is —CH═CH—CH₂—CH₂—CH(CH₃)(CH₂CH₃), and therein one —CH₂— is replaced with phenylene and one —CH₂— is replaced with —O—. nb is 1. R^{b2} is —CF₃.

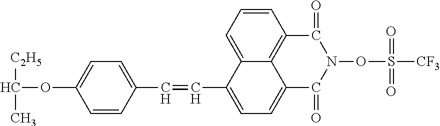 [SMILES: CCC(C)Oc1ccc(C=Cc2ccc3c4c(cccc24)C(=O)N(OS(=O)(=O)C(F)(F)F)C3=O)cc1]

The molecular weight of the acid generator (B) is preferably 400 to 1,500, and more preferably 400 to 700.

The content of the acid generator (B) is 0.1 to 10.0 mass %, and more preferably 0.5 to 1.0 mass %, based on the total mass of the polymer (A).

(C) Dissolution Rate Modifier

The composition according to the present invention comprises a dissolution rate modifier, which is a compound in which two or more of phenol structures are bonded by a hydrocarbon group optionally substituted with oxy.

The dissolution rate modifier (C) has a function of adjusting the solubility in the developer of the polymer. Although not to be bound by theory, it is considered that a preferable pattern shape is formed by the following mechanism due to the presence of the dissolution rate modifier (C). The dissolution rate modifier (C) has a phenol structure and has high solubility in an alkali developer. During development, the developer first comes into contact with the upper part of a film. At this time, only the dissolution rate modifier (C) existing near the surface in the film is dissolved in the developer. Thereby, in the vicinity of the surface of the unexposed film, the dissolution rate modifier (C) is lost, the polymer becomes to have a high molecular weight, and the solubility in an alkali developer is lowered. On the other hand, dissolution of the side of the formed resist pattern tends to be promoted, and the sectional shape of the resist pattern becomes a reverse tapered shape. By such a mechanism, the dissolution rate modifier contributes to the formation of a reverse tapered shape. Thus, the dissolution rate modifier (C) has a function of adjusting the rate through inhibiting or promoting the dissolution.

The dissolution rate modifier (C) is preferably a compound represented by the formula (c):

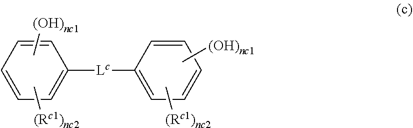

wherein,

nc1 is each independently 1, 2 or 3,

nc2 is each independently 0, 1, 2 or 3,

R^{c1} is each independently C₁₋₇ alkyl, and

L^{c} is C₁₋₁₅ divalent alkylene (this can be substituted by aryl which is optionally hydroxy-substituted, and can form a ring with a substituent of the group other than L^{c}.

nc1 is preferably each independently 1 or 2, and more preferably 1.

nc2 is preferably each independently 0, 2, or 3. In a preferred aspect, the two nc2 are identical. It is also a preferable aspect that nc2 is 0.

R^{c1} is preferably each independently methyl, ethyl or cyclohexyl, and more preferably methyl or cyclohexyl.

L^{c} is preferably C₂₋₁₂ divalent alkylene, and more preferably C₂₋₇ divalent alkylene. The aryl capable of substituting the alkylene can be not only monovalent aryl but also divalent arylene. The aryl is preferably phenyl or phenylene. The aryl can be hydroxy-substituted, but preferably one aryl is substituted by one or two of hydroxy, more preferably substituted by one hydroxy. The alkylene of Lc can be linear, branched or cyclic (preferably cyclohexalene) and any combination thereof.

An example of the ring formation with a substituent of the group other than Lc includes, for example, a ring formation with R^{c1}, or OH bonded to the phenyl to which R^{c1} is bonded. As an example of the latter ring formation, the following exemplified embodiment is indicated:

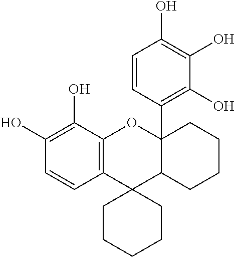 [SMILES: Oc1ccc(C23CCCCC2C2(CCCCC2)c2ccc(O)c(O)c2O3)c(O)c1O]

L^{c} is preferably —CR^{c2}R^{c3}—, where R^{c2} is hydrogen or methyl and R^{c3} is aryl or aryl-substituted alkyl, where aryl can be hydroxy-substituted.

Exemplified embodiments of the dissolution rate modifier (C) are as shown below:

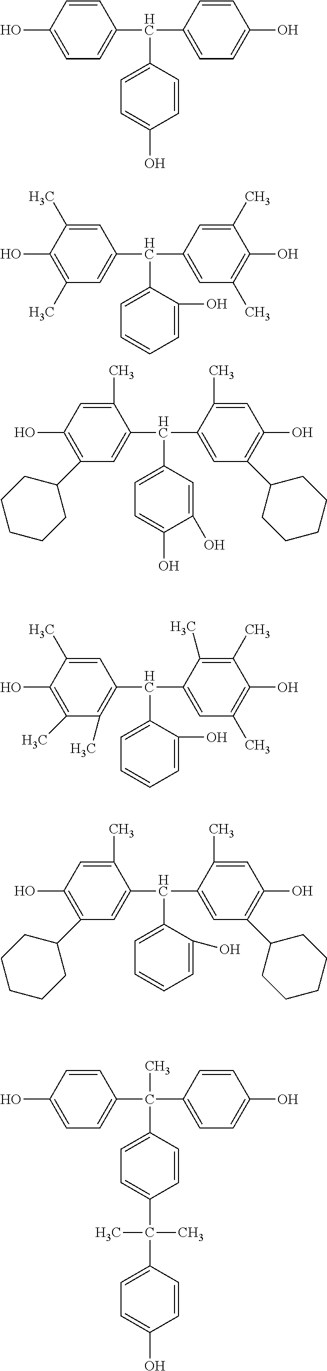

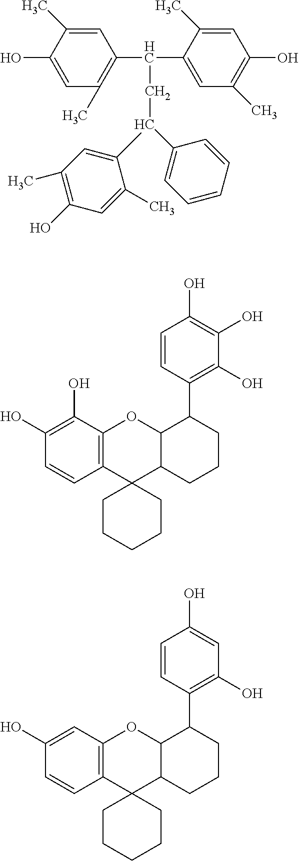 [SMILES: Cc1cc(C(CC(c2cc(C)c(O)cc2C)c2cc(C)c(O)cc2C)c2ccccc2)c(C)cc1O ; Oc1ccc(C2CCCC3C2Oc2c(ccc(O)c2O)C32CCCCC2)c(O)c1O ; Oc1ccc(C2CCCC3C2Oc2cc(O)ccc2C32CCCCC2)c(O)c1]

For example, the following exemplified embodiment can be represented by the formula (c). The two nc1 are both 1, and the two nc2 are both 2. R^{c1} is all methyl. Lc is originally a divalent alkylene of C₇, and therein one —CH₃ is replaced with phenyl and a tertiary carbon atom part of the other one isopropyl is replaced with hydroxy-substituted phenyl.

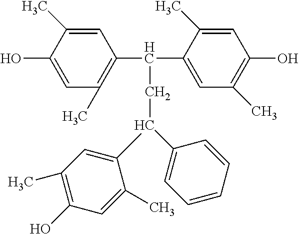 [SMILES: Cc1cc(C(CC(c2cc(C)c(O)cc2C)c2cc(C)c(O)cc2C)c2ccccc2)c(C)cc1O]

The molecular weight of the dissolution rate modifier (C) is preferably 90 to 1,500, and more preferably 200 to 900

The content of the dissolution rate modifier (C) is preferably 0.1 to 20 mass %, and more preferably 2 to 5 mass %, based on the total mass of the polymer (A).

(D) Solvent

The composition according to the present invention comprises a solvent (D). The solvent is not particularly limited so far as it can dissolve each component blended. The solvent (D) is preferably water, a hydrocarbon solvent, an ether solvent, an ester solvent, an alcohol solvent, a ketone solvent, or any combination of any of them. Exemplified embodiments of the solvent include water, n-pentane, i-pentane, n-hexane, i-hexane, n-heptane, i-heptane, 2,2,4-trimethylpentane, n-octane, i-octane, cyclohexane, methylcyclohexane, benzene, toluene, xylene, ethyl benzene, trim ethylbenzene, methylethylbenzene, n-propylbenzene, i-propylbenzene, diethylbenzene, i-butylbenzene, triethylbenzene, di-i-propylbenzene, n-amyl naphthalene, trimethyl benzene, methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethylheptanol-4, n-decanol, sec-undecyl alcohol, trimethyl nonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethyl carbinol, diacetone alcohol, cresol, ethylene glycol, propylene glycol, 1,3-butylene glycol, pentanediol-2,4,2-methylpentanediol-2,4, hexanediol-2,5, heptanediol-2,4,2-ethylhexanediol-1,3, diethylene glycol, dipropylene glycol, triethylene glycol, tripropylene glycol, glycerin, acetone, methyl ethyl ketone, methyl n-propyl ketone, methyl n-butyl ketone, diethyl ketone, methyl i-butyl ketone, methyl n-pentyl ketone, ethyl n-butyl ketone, methyl n-hexyl ketone, di-i-butyl ketone, trimethylnonane, cyclohexanone, cyclopentanone, methylcyclohexanone, 2,4-pentanedione, acetonylacetone, diacetone alcohol, acetophenone, fenthion, ethyl ether, i-propyl ether, n-butyl ether (dibutyl ether, DBE), n-hexyl ether, 2-ethylhexyl ether, ethylene oxide, 1,2-propylene oxide, dioxolane, 4-methyl dioxolane, dioxane, dimethyl dioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethyl butyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, 2-methyltetrahydrofuran, diethyl carbonate, methyl acetate, ethyl acetate, γ-butyrolactone, γ-valerolactone, n-propyl acetate, i-propyl acetate, n-butyl acetate (normal butyl acetate, nBA), i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methyl cyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate (EL), y-butyrolactone, n-butyl lactate, n-amyl lactate, diethyl malonate, dimethyl phthalate, diethyl phthalate, propylene glycol 1-monomethyl ether 2-acetate (PGMEA), propylene glycol monoethyl ether acetate, propylene glycol monopropyl ether acetate, N-methylformamide, N,N-dimethylformamide, N,N-diethylformamide, acetamide, N-methylacetamide, N,N-dimethylacetamide, N-methylpropionamide, N-methyl pyrrolidone, dimethyl sulfide, diethyl sulfide, thiophene, tetrahydrothiophene, dimethyl sulfoxide, sulfolane, and 1,3-propane sultone. These solvents can be used alone or in combination of two or more of them.

The solvent (D) preferably comprises a low boiling point solvent, and more preferably comprises 60% or more of the low boiling point solvent based on the total mass of the solvent (D).

In the present invention, the low boiling point solvent means a solvent having a boiling point at 80 to 140° C., and more preferably 110 to 130° C. The boiling point is measured under atmospheric pressure. Examples of the low boiling point solvent include PGME and nBA.

The solvent (D) is preferably PGME, EL, PGMEA, nBA,

DBE or any mixture of any of them. When the two types are mixed, the mass ratio of the first solvent to the second solvent is preferably 95:5 to 5:95 (more preferably 90:10 to 10:90). It is a preferable embodiment that the solvent (D) is a mixture of PGME and EL.

Since the solvent (D) contains at least one low boiling point solvent, the composition according to the present invention is considered to contribute to the formation of a reverse tapered shape. Although not to be bound by theory, the following mechanism is considered for this. Since the solvent (D) contains a low boiling point solvent, when the composition according to the present invention is applied on a substrate and heated, the solvent (D) is volatilized more and the amount of the solvent contained in the formed film is reduced. That is, a film having a high density is formed. Since the density of the film is high, the density of the acid generated from the acid generator (B) in the exposed area increases, and the frequency of the acid diffusion increases. As described above, since the vicinity of the surface is made to have a higher molecular weight, the influence of the diffused acid is suppressed, but the side and lower part of the pattern become to be easily affected by the diffused acid. This contributes to the formation of a reverse tapered shape. Furthermore, when the basic compound (E) is contained, as described later, the upper part of the unexposed area has an effect of inhibiting the diffusion of acid, and effect of inhibiting the diffusion is smaller at the lower part, and the reverse tapered shape is easily formed.

In relation to other layers or films, it is also one aspect that the solvent (D) contains no water. For example, the amount of water in the total solvent (D) is preferably 0.1 mass % or less, more preferably 0.01 mass % or less, and further preferably 0.001 mass % or less

The content of the solvent (D) is 40 to 90 mass %, and more preferably 30 to 50 mass %, based on the total mass of the composition. The film thickness after film formation can be controlled by increasing or decreasing the amount of the solvent in the entire composition.

(E) Basic Compound

The composition according to the present invention can further contain a basic compound (E).

The basic compound (E) has an effect of suppressing the diffusion of the acid generated in the exposed area. Then in the present invention, it is thought that the basic compound (E) plays a role which contributes to the reverse tapered shape formation. Although not to be bound by theory, the following mechanism is considered for this. At the time when the composition according to the present invention is applied on a substrate to form a film, the basic compound (E) is uniformly present in the film. Thereafter, when heated, a part of the basic compound (E) existing at the upper part in the film is volatilized into the atmosphere together with the solvent, and the part that is not volatilized moves to the upper part. Thereby, the distribution of the basic compound (E) in the film is unevenly distributed more in the upper part and less in the lower part. Upon exposure, the acid is released from the acid generator, and when this acid diffuses to the unexposed area by post exposure bake or the like, a neutralization reaction occurs with this basic compound (E), thereby the acid diffusion to the unexposed area is suppressed. However, at this time, due to the uneven distribution of the basic compound (E) in the film in the unexposed area, the effect of suppressing the acid diffusion is high at the upper part of the film, but the effect of suppressing the acid diffusion is low at the lower part of the film. That is, the acid distribution is higher at the lower part than at the upper part. This contributes to the reverse tapered shape formation when developed with an alkaline developer.

In addition to the above effects, the basic compound also has an effect of suppressing the acid deactivation on the resist film surface due to an amine component contained in the air.

The basic compound (E) is preferably selected from a group consisting of ammonia, C₁₋₁₆ primary aliphatic amine, C₂₋₃₂ secondary aliphatic amine, C₃₋₄₈ tertiary aliphatic amine, C₆₋₃₀ aromatic amine, C₅₋₃₀ heterocyclic amine, and any derivatives thereof.

Exemplified embodiments of the basic compound include ammonia, ethylamine, n-octylamine, ethylenediamine, triethylamine, triethanolamine, tripropylamine, tributylamine, triisopropanolamine, diethylamine, tris[2-(2-methoxyethoxy)ethyl]amine, 1,8-diazabicyclo-[5.4.0]undecene-7, 1,5-diazabicyclo[4.3.0]nonene-5, 7-methyl-1,5,7-triazabicyclo[4.4.0]dec-5-ene and 1,5,7-triazabicyclo[4.4.0]dec-5-ene.

The molecular weight of the basic compound (E) is preferably 17 to 500, and more preferably 100 to 350.

The content of the basic compound (E) is preferably 0 to 1.0 mass %, and more preferably 0.05 to 0.3 mass %, based on the total mass of the polymer (A). When storage stability of the composition is considered, it is also a preferred embodiment that the composition contains no basic compound (E).

(F) Plasticizer

The composition according to the present invention can further contain a plasticizer (F). By adding a plasticizer, occurrence of cracks in the resist pattern can be suppressed.

Examples of the plasticizer include alkali-soluble vinyl polymer and acid-dissociable group-containing vinyl polymer. More particularly, for example, polyvinyl chloride, polystyrene, polyhydroxystyrene, polyvinyl acetate, polyvinyl benzoate, polyvinyl ether, polyvinyl butyral, polyvinyl alcohol, polyether ester, polyvinyl pyrrolidone, polyacrylic acid, polymethacrylic acid, polyacrylic acid ester, maleic acid polyimide, polyacrylamide, polyacrylonitrile, polyvinylphenol, novolac and copolymer thereof can be referred, and polyvinyl ether, polyvinyl butyral and polyether ester are more preferable.

The plasticizer (F) preferably comprises a structural unit represented by the formula (f-1) and/or a structural unit represented by the formula (f-2).

The formula (f-1) is represented by the following:

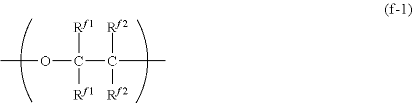

wherein,

R^{f1} is each independently hydrogen or C₁₋₅ alkyl, and

R^{f2} is each independently hydrogen or C₁₋₅ alkyl.

R^{f1} is preferably each independently hydrogen or methyl.

R^{f2} is preferably each independently hydrogen or methyl.

More preferably, one of the two R^{f1} and the two R^{f2} is methyl and the remaining three are hydrogen.

The formula (f-2) is represented by the following:

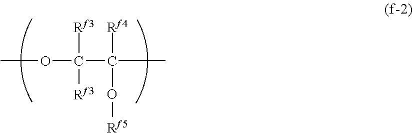

wherein,

R^{f3} is each independently hydrogen or C₁₋₅ alkyl,

R^{f4} is hydrogen or C₁₋₅ alkyl, and

R^{f5} is C₁₋₅ alkyl.

Preferably, R^{f3} is each independently hydrogen or methyl, and more preferably both are hydrogen.

R^{f4} is preferably hydrogen or methyl, and more preferably hydrogen.

R^{f5} is preferably methyl or ethyl, and more preferably methyl.

Exemplified embodiments of the plasticizer (F) are as shown below:

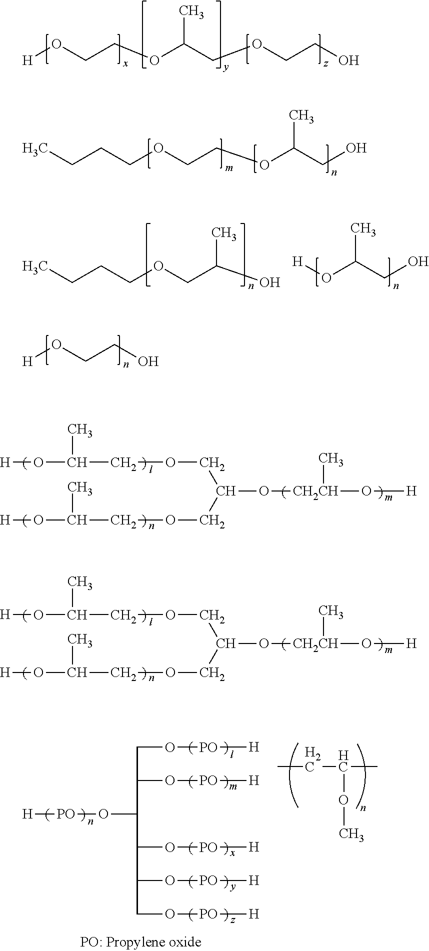

The mass average molecular weight of the plasticizer (F) is preferably 1,000 to 50,000, more preferably 1,500 to 30,000, further preferably 2,000 to 21,000, and still more preferably 3,000 to 21,000.

The content of the plasticizer (F) is preferably 0 to 30 mass %, and more preferably 1 to 10 mass %, based on the total mass of the polymer (A). It is also a preferred aspect of the present invention that the composition contains no plasticizer.

(G) Additive

The composition according to the present invention can contain an additive (G) other than (A) to (F). The additive (G) is not particularly limited, but is preferably at least one selected from the group consisting of a surfactant, an acid, and a substrate adhesion enhancer.

The content of the additive (G) is 0 to 20 mass %, and more preferably 0 to 11 mass %, based on the total mass of the polymer (A). It is a suitable example of the composition according to the present invention that the composition contains no additive (G) (0 mass %).

By including a surfactant, coatability can be improved. As the surfactant that can be used in the present invention, (I) an anionic surfactant, (II) a cationic surfactant or (III) a nonionic surfactant can be referred, and more particularly, (I) alkyl sulfonate, alkylbenzene sulfonic acid and alkylbenzene sulfonate, (II) lauryl pyridinium chloride and lauryl methyl ammonium chloride, and (III) polyoxyethylene octyl ether, polyoxyethylene lauryl ether and polyoxy ethylene acetylenic glycol ether are preferred.

These surfactants can be used alone or combination of two or more of them, and the content thereof is preferably 2 mass % or less, and more preferably 1 mass % or less, based on the total mass of the polymer (A).

The acid can be used to adjust pH value of the composition and improve the solubility of the additive component. Although the acid to be used is not particularly limited, for example, formic acid, acetic acid, propionic acid, benzoic acid, phthalic acid, salicylic acid, lactic acid, malic acid, citric acid, oxalic acid, malonic acid, succinic acid, fumaric acid, maleic acid, aconitic acid, glutaric acid, adipic acid, and combination thereof can be referred. The content of the acid is preferably 0.005 to 0.1 mass % (50 to 1,000 ppm) based on the total mass of the composition.

Using the substrate adhesion enhancer, it is possible to prevent the pattern from being peeled off due to the stress applied during film formation. As the substrate adhesion enhancer, imidazoles and silane coupling agents are preferable. Among imidazoles, 2-hydroxybenzimidazole, 2-hydroxyethylbenzimidazole, benzimidazole, 2-hydroxyimidazole, imidazole, 2-mercaptoimidazole and 2-aminoimidazole are preferred, and 2-hydroxybenzimidazole, benzimidazole, 2-hydroxyimidazole and imidazole are more preferably used. The content of the substrate adhesion enhancer is preferably 0 to 10 mass %, more preferably 0 to 5 mass %, further preferably 0.01 to 5 mass %, and still more preferably 0.1 to 3 mass %, based on the total mass of the polymer (A).

<Method for Manufacturing Resist Pattern>

The method for manufacturing a resist pattern according to the present invention comprises the following processes:

(1) applying the composition according to the present invention above a substrate;

(2) heating the composition to form a resist layer;

(3) exposing the resist layer;

(4) subjecting the resist layer to post exposure bake; and

(5) developing the resist layer.

Although describing for clarity, the numbers in parentheses mean the order. For example, the process (1) is performed before the process (2).

Hereinafter, one aspect of the manufacturing method according to the present invention is described.

The composition according to the present invention is applied above a substrate (for example, a silicon/silicon dioxide coated substrate, a silicon nitride substrate, a silicon wafer substrate, a glass substrate, an ITO substrate, and the like) by an appropriate method. Here, in the present invention, the “above” includes the case where a layer is formed immediately above a substrate and the case where a layer is formed above a substrate via another layer. For example, a planarization film or resist underlayer can be formed immediately above a substrate, and the composition according to the present invention can be applied immediately above the film. The application method is not particularly limited, and examples thereof include a method using a spinner or a coater. After application, the resist layer is formed by heating. The heating of (2) is performed, for example, by a hot plate. The heating temperature is preferably 60 to 140° C., and more preferably 90 to 110° C. The temperature here is a temperature of heating atmosphere, for example, that of a heating surface of a hot plate. The heating time is preferably 30 to 900 seconds, and more preferably 60 to 300 seconds. The heating is preferably performed in an air or a nitrogen gas atmosphere.

The film thickness of the resist layer is selected depending on the purpose, but when the composition according to the present invention is used, a pattern having a better shape can be formed at the time of forming a thick coating film. For this reason, it is preferable that the thickness of the resist film is thicker, for example, preferably 1 μm or more, and more preferably 5 μm or more.

The resist layer is exposed through a predetermined mask. The wavelength of light to be used for exposure is not particularly limited, but the exposure is performed with light having a wavelength of preferably 190 to 440 nm. Particularly, KrF excimer laser (wavelength: 248 nm), ArF excimer laser (wavelength: 193 nm), i-line (wavelength: 365 nm), h-line (wavelength: 405 nm), g-line (wavelength: 436 nm), or the like can be used. The wavelength is more preferably 240 to 440 nm, further preferably 360 to 440 nm, and still more preferably 365 nm. These wavelengths allow a range of ±1%.

After exposure, a post exposure bake (hereinafter sometimes referred to as PEB) is performed. The heating of (4) is performed, for example, by a hot plate. The temperature of post exposure bake is preferably 80 to 160° C., more preferably 105 to 115° C., and the heating time is 30 to 600 seconds, preferably 60 to 200 seconds. Heating is preferably performed in an air or a nitrogen gas atmosphere.

After the PEB, development is performed using a developer. As the developing method, a method conventionally used for developing a photoresist, such as a paddle developing method, an immersion developing method, or a swinging immersion developing method, can be used. Further, as the developer, aqueous solution containing inorganic alkalis, such as sodium hydroxide, potassium hydroxide, sodium carbonate and sodium silicate; organic amines, such as ammonia, ethylamine, propylamine, diethylamine, diethylaminoethanol and triethylamine; quaternary amines, such as tetramethylammonium hydroxide (TMAH); and the like are used, and a 2.38 mass % TMAH aqueous solution is preferable. A surfactant can be further added to the developer. The temperature of the developer is preferably 5 to 50° C., more preferably 25 to 40° C., and the development time is preferably 10 to 300 seconds, more preferably 30 to 60 seconds. After development, washing or rinsing can also be performed as necessary. Since a positive type resist composition is used, the exposed area is removed by development to form a resist pattern. The resist pattern can also be further made finer, for example, using a shrink material.

Since the unexposed area is hardly dissolved in the developer by development, the thickness of the formed resist pattern and that of the above-described resist layer can be regarded as identical.

Using the composition of the present invention, a resist pattern of reverse tapered shape can be formed. Here, in the present invention, the reverse tapered shape means that when a resist pattern 12 is formed on a substrate 11 as shown in the sectional view of FIG. 1(A), the angle formed by a straight line (taper line), which connects the opening point (a boundary between the resist surface and the side of the resist pattern) 13 and the bottom point (a boundary between the substrate surface and the side of the resist pattern) 14, and the substrate surface is larger than 90 degrees, and the resist pattern does not substantially protrude to the outside of the taper line, that is, the resist pattern is not substantially thickened. Here, this angle is referred to as the taper angle 15. Such a resist pattern is referred to as the resist pattern of reverse tapered shape 12. In addition, in the present invention, the reverse tapered shape not only means a reverse truncated cone but also includes the cases that, in a linear pattern, the line width of the surface part is wider than the line width in the vicinity of the substrate, or the like.

In the resist pattern of reverse tapered shape according to the present invention, as shown in the sectional view of FIG. 1(B), the case where the resist pattern cavates to the inside from the straight line (taper line 24) connecting the opening point 22 and the bottom point 23, that is, the case where the resist pattern is thin, is also included. The taper angle here is the taper angle 25. Such a resist pattern is referred to as the resist pattern of overhanging shape 21. A straight line is drawn in parallel with the substrate surface at a position of the height of a half-length 27 of the resist pattern film thickness 26 from the substrate, and on the straight line, the distance between its intersection with the resist pattern and its intersection with the taper line is referred to as the bitten width 28. Similarly, on the straight line, the distance between its intersection with the resist pattern and its intersection with a straight line drawn perpendicularly to the substrate from the opening point is referred to as the taper width 29. The case where the bitten width/taper width is larger than 0 falls under FIG. 1(B), and the case where it is 0 falls under FIG. 1(A).

In the case of the overhanging shape, the remover tends to enter during resist removing after metal deposition, so that it is preferable.

In addition, as a modified example of the overhanging shape, a case where the end of the resist pattern 31 is rounded as shown in FIG. 1(C) is also considered. In this case, the opening point 32 is a boundary between the resist surface and the side of the resist pattern, and upon assuming a plane of the resist surface that is parallel to the bottom surface, it is a point where the resist pattern leaves the plane. The bottom point 33 is a boundary between the substrate surface and the side of the resist pattern. A straight line connecting the opening point 32 and the bottom point 33 is the taper line 34, and the taper angle here is the taper angle 35.

The area of the portion that is inside the taper line but is not the part of the resist pattern is referred to as Sᵢₙ 36, and the area of the portion that is outside the taper line but is the resist pattern is referred to as Sₒᵤₜ 37. In the case of a plurality, sum of the area is used.

Sₒᵤₜ/(Sᵢₙ+Sₒᵤₜ) is preferably 0 to 0.45, more preferably 0 to 0.1, further preferably 0 to 0.05, and still more preferably 0 to 0.01. The shape having a small Sₒᵤₜ/(Sᵢₙ+Sₒᵤₜ) is advantageous because the remover can easily enter the resist side wall even if the metal is thickly deposited on the resist pattern. In addition, the T-type resist pattern disclosed in Patent Document 3 has Sₒᵤₜ/(Sᵢₙ+Sₒᵤₜ) of about 0.5.

(Sᵢₙ−Sₒᵤₜ)/(Sᵢₙ+Sₒᵤₜ) is preferably 0 to 1, more preferably 0.55 to 1, further preferably 0.9 to 1, and still more preferably 0.99 to 1. It is also a preferred aspect of the present invention that 0<(Sᵢₙ−Sₒᵤₜ)/(Sᵢₙ+Sₒᵤₜ). When (Sᵢₙ−Sₒᵤₜ)/(Sᵢₙ+Sₒᵤₜ) is large, the resist pattern as a whole is dented to the inside from the taper line, and even if the metal is thickly deposited on the resist pattern, the remover can easily enter the resist sidewall, so that it is preferable.

Upon applying the above to the case of the shapes of FIG. 1(A) and FIG. 1(B), both are Sₒᵤₜ/(Sᵢₙ+Sₒᵤₜ)=0, and both are (Sᵢₙ−Sₒᵤₜ)/(Sᵢₙ+Sₒᵤₜ)=1.

It is known that when a resist pattern is formed using a chemically amplified resist, the shape of the resist pattern changes if the time left standing from exposure to PEB (PED: Post Exposure Delay) becomes longer. This phenomenon is considered to be due to the fact that the acid generated in the exposed area of the resist is neutralized by a basic compound (for example, amine component) in the air, and the solubility of the resist film surface in the exposed area is lowered. The top part of the resist film is easily affected by this, and a part of the exposed area of the top part sometimes remains undeveloped.

The composition according to the present invention is less susceptible to the shape change as described above than the conventionally known composition. That is, it has a feature of being strong against environmental impact.

Furthermore, a metal pattern can be manufactured by a method comprising the following processes:

(6) depositing metal above a substrate using the resist pattern as a mask; and

(7) removing the resist pattern with a remover.

Using the resist pattern as a mask, metal such as gold and copper (this can be metal oxide or the like) is deposited above the substrate. In addition to deposition, sputtering can be used.

Thereafter, the metal pattern can be formed by removing the resist pattern together with the metal formed on its upper part using the remover. The remover is not particularly limited as long as it is used as a remover for resist, but, for example, N-methylpyrrolidone (NMP), acetone, and an alkaline solution are used. Since the resist pattern according to the present invention has a reverse tapered shape, the metal on the resist pattern is separated from the metal formed on the area where the resist pattern is not formed, and therefore can be easily removed. Further, the film thickness of the formed metal pattern can be increased, and a metal pattern having a film thickness of preferably 0.01 to 40 μm, more preferably 1 to 5 μm is formed.

As another embodiment of the present invention, various substrates that serve as bases can also be patterned using the resist pattern formed up to the process (5) as a mask. The substrate can be processed directly using the resist pattern as a mask, or can be processed via an intermediate layer. For example, a resist underlayer can be patterned using the resist pattern as a mask, and the substrate can be patterned using the resist underlayer pattern as a mask. A known method can be used for processing, but a dry etching method, a wet etching method, an ion implantation method, a metal plating method, or the like can be used. It is also possible to wire electrodes or the like on the patterned substrate.

Thereafter, if necessary, the substrate is further processed to form a device. For these further processing, known methods can be applied. After forming the device, if necessary, the substrate is cut into chips, which are connected to a lead frame and packaged with resin. In the present invention, this packaged product is referred to as the device. Examples of the device include a semiconductor device, a liquid crystal display device, an organic EL display device, a plasma display device, and a solar cell device. The device is preferably a semiconductor.

### EXAMPLES

The present invention is described below with reference to various examples. In addition, the aspect of the present invention is not limited only to these examples.

### Example 1: Preparation of Composition 1

To 170 mass parts of a mixed solvent composed of PGME:EL=85:15 (mass ratio), 50 mass parts of the following P1 as the polymer P and 50 mass parts of the following Q1 as the polymer Q are added. To this, based on the total mass of the entire composition, 1.6 mass % of the following B1 as an acid generator, 2.5 mass % of the following C1 as a dissolution rate modifier, 0.1 mass % of tris[2-(2-methoxyethoxy)ethyl]amine as a basic compound, 5.0 mass % of the following F1 as a plasticizer, and 0.1 mass % of KF-53 (Shin-Etsu Chemical) as a surfactant are respectively added. This is stirred at room temperature for 5 hours. It is visually confirmed that the additives are dissolved. This is filtered through a 1.0 μm filter. Thereby, Composition 1 is obtained. The viscosity of Composition 1 is 600 cP when measured at 25° C. by the Canon-Fenske method.

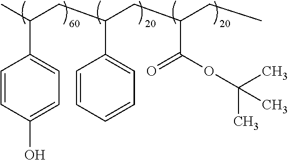

(P1) hydroxystyrene-styrene-t-butyl acrylate copolymer, Toho Chemical, 60:20:20 at each molar ratio, Mw: about 12,000

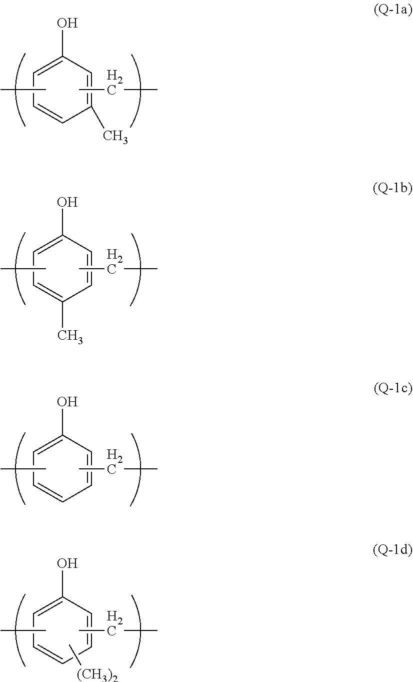

(Q1) polymer of (Q-1a):(Q-1b):(Q-1c):(Q-1d)=60:40:0:0, Sumitomo Bakelite, Mw: about 5,000

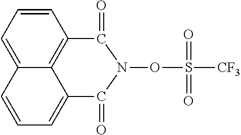 [SMILES: O=C1c2cccc3cccc(c23)C(=O)N1OS(=O)(=O)C(F)(F)F]

### (B1) NIT, Heraeus

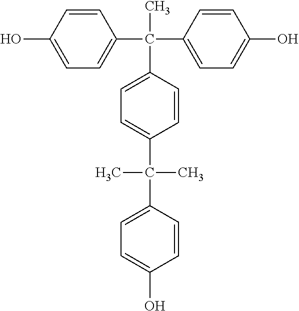 [SMILES: CC(C)(c1ccc(O)cc1)c1ccc(C(C)(c2ccc(O)cc2)c2ccc(O)cc2)cc1]

### (C1) TPPA-MF, Honshu Chemical

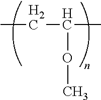

### (F1) Lutonal, BASF

Examples 2 to 10 and Comparative Examples 1 to 3: Preparation of Compositions 2 to 10 and Comparative Compositions 1 to 2

Compositions 2 to 10 and Comparative Compositions 1 to 3 are obtained in the same manner as Composition 1 except that the polymer and the dissolution rate modifier are changed as shown in Table 1.

TABLE 1

| | | | Composition | | | | | | | | |
|---|---|---|---|---|---|---|---|---|---|---|---|
| | | | Polymer | | | | | | Dissolution | Film | |
| | | | P | Polymer Q | | | | | rate | thick- | |
| | | | parts by | parts | Constitution (mol ratio | | | | modifier | ness | Taper |
| | | | mass | by | Q-1a | Q-1b | Q-1c | Q-1d | mass % | μm | angle |
| Example | 1 | Composition 1 | 50 | 50 | 60 | 40 | 0 | 0 | 2.5 | 11.8 | 100° |
| | 2 | Composition 2 | 50 | 50 | 40 | 40 | 0 | 20 | 2.5 | 11.8 | 110° |
| | 3 | Composition 3 | 50 | 50 | 36 | 24 | 24 | 0 | 2.5 | 10.8 | 113° |
| | 4 | Composition 4 | 50 | 50 | 45 | 45 | 0 | 10 | 2.5 | 11.4 | 112° |
| | 5 | Composition 5 | 50 | 50 | 42.5 | 42.5 | 0 | 15 | 2.5 | 11.6 | 112° |
| | 6 | Composition 6 | 50 | 50 | 37.5 | 37.5 | 0 | 25 | 2.5 | 11.7 | 111° |
| | 7 | Composition 7 | 50 | 50 | 60 | 40 | 0 | 0 | 5 | 11.9 | 108° |
| | 8 | Composition 8 | 50 | 50 | 60 | 40 | 0 | 0 | 10 | 11.6 | 101° |
| | 9 | Composition 9 | 50 | 50 | 60 | 40 | 0 | 0 | 20 | 11.6 | 99° |
| | 10 | Composition 10 | 100 | 0 | — | — | — | — | 5 | 11.3 | 93° |
| Compar- | 1 | Comparative | 50 | 50 | 60 | 40 | 0 | 0 | — | 11.9 | below |
| ative | | Composition 1 | | | | | | | | | 90° |
| Example | 2 | Comparative | 0 | 100 | 60 | 40 | 0 | 0 | 5 | 11.2 | below |
| | | Composition 2 | | | | | | | | | 90° |
| | 3 | Comparative | 30 | 70 | 60 | 40 | 0 | 0 | 5 | 11.8 | below |
| | | Composition 3 | | | | | | | | | 90° |

Formation of Resist Pattern

The following operation is performed using the compositions obtained above to obtain a resist pattern.

Each composition is dropped onto a 6-inch silicon wafer using LITHOTRAC (Litho Tech Japan) and spin-coated to form a resist layer. The wafer on which the resist layer is formed is baked at 100° C. for 180 seconds using a hot plate. After baking, the film thickness of the resist layer is measured using an optical interference type film thickness measuring apparatus Lambda Ace VM-12010 (SCREEN). The film thickness is measured at 8 points on the wafer excluding the central part, and the average value thereof is used. The obtained film thickness is shown in Table 1.

Then, exposure is performed with i-line (365 nm) using Suss Aligner (Suss MicroTec). After exposure, the wafer is subjected to post exposure bake on a hot plate at 120° C. for 120 seconds. This is paddle-developed with a 2.38% TMAH aqueous solution for 60 seconds. Thereby, a resist pattern of Line=10 μm and Space (trench)=10 μm (Line:Space=1:1) is obtained.

When the ratio of the mask size and the pattern size become 1:1, the exposure energy (mJ/cm²) is 120 mJ/cm² in the case of Example 1.

Evaluation of Taper Angle

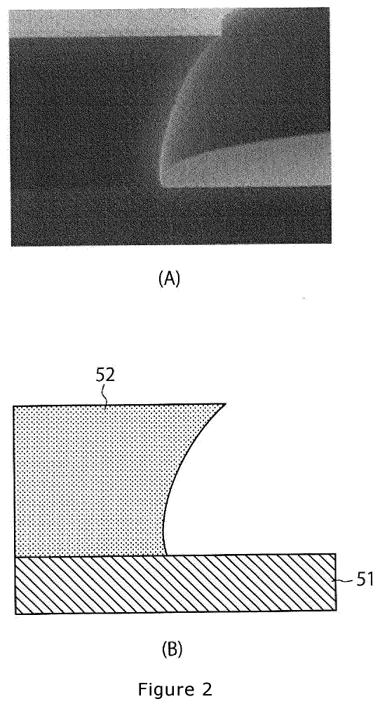

The sectional shape of the obtained resist pattern is observed using a scanning electron microscope SU8230 (Hitachi Technology), and the taper angle defined above is measured. In addition, the sectional shape of the resist pattern formed in Example Composition 5 is shown in FIG. 2(A). In addition, FIG. 2(B) schematically shows a sectional view thereof. The results obtained are shown in Table 1.

As to the sectional shape of the resist pattern formed in Example Composition 5, Sₒᵤₜ/(Sᵢₙ+Sₒᵤₜ)=0, and (Sᵢₙ−Sₒᵤₜ)/(Sᵢₙ+Sₒᵤₜ)=1 in accordance with the above definition.

Evaluation of Crack Resistance

Based on the composition of Example Composition 1 (this contains 5 mass % of the plasticizer), a composition containing no plasticizer, one containing 2.5 mass % of the plasticizer, one containing 7.5 mass % of the plasticizer and one containing 10.0 mass % of the plasticizer are prepared, a resist pattern is formed in the same manner as described above, and gold is deposited using a sputtering apparatus. Thereafter, the presence or absence of cracks is visually confirmed with an optical microscope. In the case where no plasticizer is contained, cracks are slightly confirmed, but in the case where 2.5 mass % of the plasticizer is contained, cracks are reduced as compared with the case where no plasticizer is contained. In the case where 5 mass %, 7.5 mass % or 10.0 mass % of the plasticizer is contained, no cracks are observed.

### EXPLANATION OF SYMBOLS

11. substrate
12. resist pattern of reverse tapered shape
13. opening point
14. bottom point
15. taper angle
21. resist pattern of overhanging shape
22. opening point
23. bottom point
24. taper line
25. taper angle
26. resist pattern film thickness
27. half-length of resist pattern film thickness
28. bitten width
29. taper width
31. resist pattern
32. opening point
33. bottom point
34. taper line
35. taper angle
36. Sᵢₙ
37. Sₒᵤₜ
51. substrate
52. resist pattern

1-15. (canceled)

16. A positive type resist composition comprising:
(A) at least one polymer selected from the group consisting of:
polymer P comprising a repeating unit selected from the group consisting of the formulae (P-1) to (P-4): 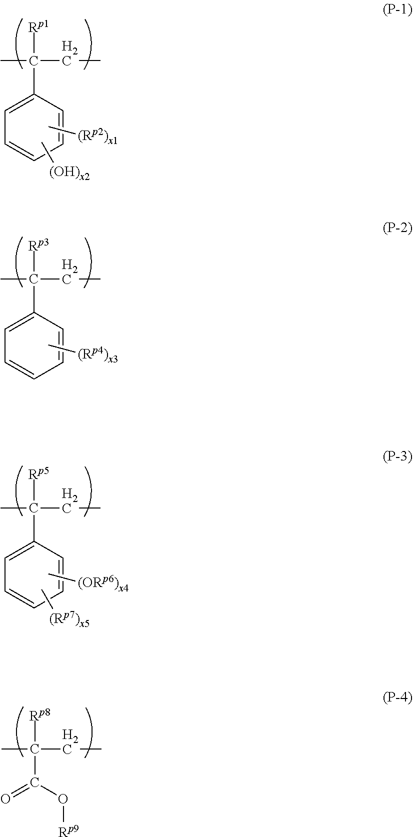
wherein,
R^{p1}, R^{p3}, R^{p5} and R^{p8} are each independently C₁₋₅ alkyl, C₁₋₅ alkoxy or —COOH,
R^{p2}, R^{p4} and R^{p7} are each independently C₁₋₅ alkyl (where —CH₂— in alkyl can be replaced with —O—,
R^{p6} and R^{p9} are each independently C₁₋₅ alkyl where —CH₂— in alkyl can be replaced with —O—,
x1 is 0 to 4,
x2 is 1 to 2, provided that x1+x2≤5,
x3 is 0 to 5,
x4 is 1 to 2,
x5 is 0 to 4, provided that x4+x5≤5, and
polymer Q comprising a repeating unit represented by the formula (Q-1): 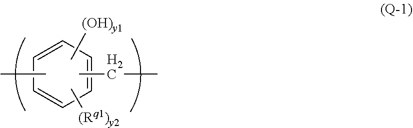
wherein,
R^{q1} is independently C₁₋₅ alkyl,
y1 is 1 to 2, and
y2 is 0 to 3, provided that y1+y2≤4,
provided that the total mass of the polymer P (Mₚ) and the total mass of the polymer Q (M_{q}) in the composition satisfy the formulae: 0<Mₚ/(Mₚ+M_{q})≤100% and 0≤M_{q}/(Mₚ+M_{q})<70%;
(B) an acid generator having an imide group;
(C) a dissolution rate modifier, which is a compound in which two or more of phenol structures are bonded by a hydrocarbon group optionally substituted by oxy; and
(D) a solvent.

17. The composition according to claim 16, wherein 10≤M_{q}/(Mₚ+M_{q})≤60%.

18. The composition according to claim 16, wherein the polymer Q comprises a repeating unit selected from the group consisting of the formulae (Q-1a) to (Q-1d): 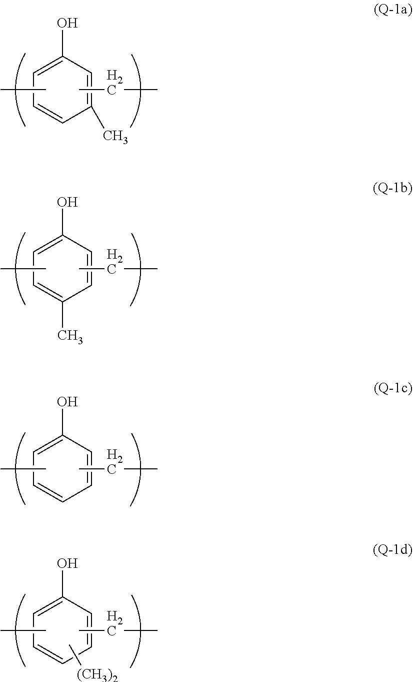
wherein,
N_{qa} that is the number of the repeating unit of (Q-1a), N_{qb} that is the number of the repeating unit of (Q-1b), N_{qc} that is the number of the repeating unit of (Q-1c), and N_{qd} that is the number of the repeating unit of (Q-1d) satisfy the following formulae:
30%≤N_{qa}/(N_{qa}+N_{qb}+N_{qc}+N_{qd})≤100%;
0%≤N_{qb}/(N_{qa}+N_{qb}+N_{qc}+N_{qd})≤70%;
0%≤N_{qc}/(N_{qa}+N_{qb}+N_{qc}+N_{qd})≤50%; and
0%≤N_{qd}/(N_{qa}+N_{qb}+N_{qc}+N_{qd})≤70%.

19. The composition according to claim 16, wherein the composition further comprises (E) a basic compound.

20. The composition according to claim 16, wherein the composition further comprises (E) a basic compound, and preferably the composition further comprises (F) a plasticizer.

21. The composition according to claim 16, wherein the content of the acid generator (B) is 0.1 to 10.0 mass % based on the total mass of the polymer (A),
the content of the polymer (A) is 10 to 50 mass % based on the total mass of the composition,
the content of the dissolution rate modifier (C) is 0.1 to 20 mass % based on the total mass of the polymer (A),
the content of the solvent (D) is 40 to 90 mass % based on the total mass of the composition,
the content of the basic compound (E) is 0 to 1.0 mass % based on the total mass of the polymer (A), and
the content of the plasticizer (F) is 0 to 30 mass % based on the total mass of the polymer (A).

22. The composition according to claim 16, wherein,
the acid generator (B) is represented by the formula (b): 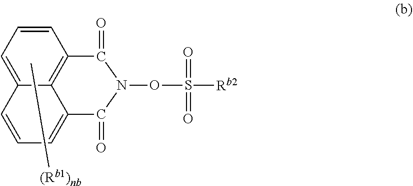
wherein,
R^{b1} is each independently C₃₋₁₀ alkenyl or alkynyl (where CH₃— in alkenyl and alkynyl can be substituted by phenyl, and —CH₂— in alkenyl and alkynyl can be replaced with at least any one of —C(═O)—, —O— or phenylene), C₂₋₁₀ thioalkyl or C₅₋₁₀ saturated heterocyclic ring,
nb is 0, 1 or 2, and
R^{b2} is C₁₋₅ fluorine-substituted alkyl;
the dissolution rate modifier (C) is represented by the formula (c): 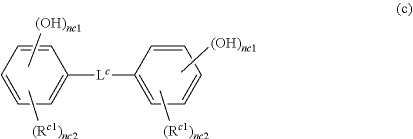
wherein,
nc1 is each independently 1, 2 or 3,
nc2 is each independently 0, 1, 2 or 3,
R^{c1} is each independently C₁₋₇ alkyl,
L^{c} is C₁₋₁₅ divalent alkylene which can be substituted by aryl which is optionally hydroxy-substituted, and can form a ring with a substituent of the group other than L^{c};
the basic compound (E) is selected from a group consisting of ammonia, C₁₋₁₆ primary aliphatic amine, C₂₋₃₂ secondary aliphatic amine, C₃₋₄₈ tertiary aliphatic amine, C₆₋₃₀ aromatic amine, C₅₋₃₀ heterocyclic amine, and any derivatives thereof; and/or
the plasticizer (F) is a compound comprising a structural unit represented by the formula (f-1): 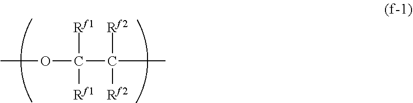
wherein,
R^{f1} is each independently hydrogen or C₁₋₅ alkyl, and R^{f2} is each independently hydrogen or C₁₋₅ alkyl, and/or the formula (f-2): 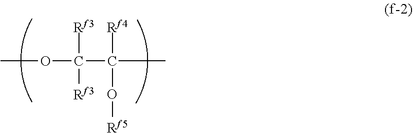
wherein,
R^{f3} is each independently hydrogen or C₁₋₅ alkyl,
R^{f4} is hydrogen or C₁₋₅ alkyl, and
R^{f5} is C₁₋₅ alkyl.

23. The composition according to claim 16, wherein the viscosity of said composition is 50 to 2,000 cP at 25° C.

24. The composition according to claim 16, which is a positive type resist composition forming reverse tapered shape.

25. The composition according to claim 16, which is a positive type lift-off resist composition.

26. A method for manufacturing a resist pattern comprising the following processes:
(1) applying the composition according to claim 16 above a substrate;
(2) heating said composition to form a resist layer;
(3) exposing said resist layer;
(4) subjecting said resist layer to post exposure bake; and
(5) developing said resist layer.

27. The method according to claim 26, wherein the film thickness of said resist pattern is 1 to 50 μm.

28. The method according to claim 26, wherein said resist pattern has a reverse tapered shape.

29. A method for manufacturing a metal pattern comprising the following processes:
manufacturing a resist pattern by the method according to claim 26;
(6) depositing metal above a substrate using the resist pattern as a mask; and
(7) removing the resist pattern with a remover.

30. The method according to claim 27, wherein the film thickness of said metal pattern is 0.01 to 40 μm.

31. A method for manufacturing a device comprising the method according to claim 25.
